(19) United States
(12) Patent Application Publication
(10) Pub. No.: US 2014/0285972 A1
(43) Pub. Date: Sep. 25, 2014

(54) HOUSING AND POWER MODULE HAVING THE SAME

(71) Applicant: SAMSUNG ELECTRO-MECHANICS CO., LTD., Suwon (KR)

(72) Inventors: Chang Seob Hong, Suwon (KR); Young Hoon Kwak, Suwon (KR); Kwang Soo Kim, Suwon (KR); Bum Seok Suh, Suwon (KR)

(73) Assignee: SAMSUNG ELECTRO-MECHANICS CO., LTD., Suwon (KR)

(21) Appl. No.: 13/904,710

(22) Filed: May 29, 2013

(30) Foreign Application Priority Data
Mar. 21, 2013 (KR) 10-2013-0030169

(51) Int. Cl. H05K 7/14; H05K 7/20

(52) U.S. Cl. CPC H05K 7/14; H05K 7/20436
USPC 361/707

(57) ABSTRACT

There are provided a housing capable of evenly distributing stress generated at the time of assembly thereof and a power module having the same. The housing for a power module according to an embodiment of the invention includes: a body part having a space formed therein, the space receiving a module substrate having electronic devices mounted thereon; a plurality of fastening parts protruded from sides of the body part; and a fastening member having a leaf spring form and having both ends coupled to two of the fastening parts, respectively, wherein the fastening member includes: a coupling portion coupled to a fixing member; and elastic portions extending from both edges of the coupling portion to be coupled to the fastening parts and elastically deformed when the coupling portion is fastened to a heat radiating substrate to provide elastic force to the fastening parts.

### CROSS-REFERENCE TO RELATED APPLICATIONS

This application claims the priority of Korean Patent Application No. 10-2013-0030169 filed on Mar. 21, 2013, in the Korean Intellectual Property Office, the disclosure of which is incorporated herein by reference.

### BACKGROUND OF THE INVENTION

1. Field of the Invention

The present invention relates to a housing and a power module having the same, and more particularly, to a housing capable of evenly distributing stress generated at the time of assembly thereof and a power module having the same.

2. Description of the Related Art

In terms of power modules, as amounts of heat generated thereby are increased due to increases in energy consumption and the tendency for the miniaturization and integration of elements included therein, a need to increase cooling efficiency in power modules has arisen.

Since heat generated in the power module may greatly affect a lifespan of elements thereof, due to thermal deformation of a structure, a great deal of research into a structure for increasing cooling performance has been conducted.

However, a relatively intricate structure for increasing efficiency may result in increased manufacturing costs at the time of mass production, and thus, a high-efficiency structure able to be simplified and easily manufactured is required.

In addition to this, a heat transfer rate maybe reduced due to warpage occurring due to the bonding of various materials having different coefficients of thermal expansion, and thus, thermal resistance may be increased, such that the cooling performance may be degraded. Therefore, a need exists for a method of improving structural flatness in a substrate.

Meanwhile, the power module according to the related art is manufactured in a manner in which a housing is coupled to a heat sink for cooling and a substrate on which semiconductor devices are mounted is disposed therebetween.

In this case, a method for fastening the housing to the heat sink by directly inserting a screw into a hole formed in the housing has mainly been used.

However, the power module according to the related art has a problem in that stress may be intensively applied to a portion of the housing in which the screw is provided, due to screw fastening. Further, the foregoing problem may lead to damage to the housing and degrade contact reliability between the substrate and the housing, thereby degrading efficiency of the power module.

### RELATED ART DOCUMENT

(Patent Document 1) Korean Patent Laid-Open Publication No. 1999-012187

### SUMMARY OF THE INVENTION

An aspect of the present invention provides a housing capable of evenly distributing stress generated in the housing at the time of assembly thereof and a power module having the same.

Another aspect of the present invention provides a housing in which damage to a fastening portion thereof may be minimized and a power module having the same.

According to an aspect of the present invention, there is provided a housing for a power module, including: a body part having a space formed therein, the space receiving a module substrate having electronic devices mounted thereon; a plurality of fastening parts protruded from sides of the body part; and a fastening member having a leaf spring form and having both ends coupled to two of the fastening parts, respectively, wherein the fastening member includes: a coupling portion coupled to a fixing member; and elastic portions extending from both edges of the coupling portion to be coupled to the fastening parts and elastically deformed when the coupling portion is fastened to a heat radiating substrate to provide elastic force to the fastening parts.

The elastic portions of the fastening member may include at least one curved portion or at least one bent portion.

Both ends of the fastening members may be provided with fixing portions having expanded dimensions and the fixing portions may limit deformation of the fastening member.

The coupling portion of the fastening member may be disposed to be higher than a lower surface of the body part.

The fastening parts may be provided with fitting grooves into which the elastic portions are inserted.

The body part may have a rectangular parallelepiped shape and the fastening parts may be formed on at least two of the sides of the body part, and one side of the at least two of the sides of the body part may be provided with two fastening parts disposed in a symmetrical manner.

The body part may include at least one or more through holes through which external connection terminals mounted on the module substrate are exposed to the outside.

According to another aspect of the present invention, there is provided a housing for a power module, including: a plurality of fastening parts protruded from sides of a body part; and a fastening member having both ends coupled to two of the fastening parts, respectively, and a central portion fastened to a heat radiating substrate by a fixing member.

According to another aspect of the present invention, there is provided a power module, including: a heat radiating substrate; a module substrate disposed on the heat radiating substrate and having at least one electronic device mounted thereon; and a housing receiving the module substrate and fastened to the heat radiating substrate, wherein the housing includes: a plurality of fastening parts protruded from sides thereof; and a fastening member having a leaf spring form and having both ends coupled to two of the fastening parts, respectively.

The fastening member may include: a coupling portion surface-contacting the heat radiating substrate through a fixing screw to be fixedly coupled thereto; and elastic portions extending from both edges of the coupling portion, respectively, to be coupled to the fastening parts and elastically deformed when the coupling portion is fastened to the heat radiating substrate to provide elastic force to the fastening parts.

The fastening parts may be provided with fitting grooves into which the elastic portions are inserted, and the elastic portion may be elastically deformed within the fitting grooves.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically illustrating a power module according to an embodiment of the present invention;

FIG. 2 is a perspective view illustrating only a housing and a substrate of the power module illustrated in FIG. 1;

FIG. 3 is an exploded perspective view of FIG. 2;

FIG. 4 is a plan view schematically illustrating the housing of FIG. 2;

FIG. 5 is a bottom perspective view schematically illustrating the housing of FIG. 2;

FIG. 6 is a side view in direction A of FIG. 4;

FIG. 7 is a side view in direction B of FIG. 1; and

FIG. 8 is a partially enlarged view of portion C of FIG. 7.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements maybe exaggerated for clarity, and the same reference numerals will be used throughout to designate the same or like elements.

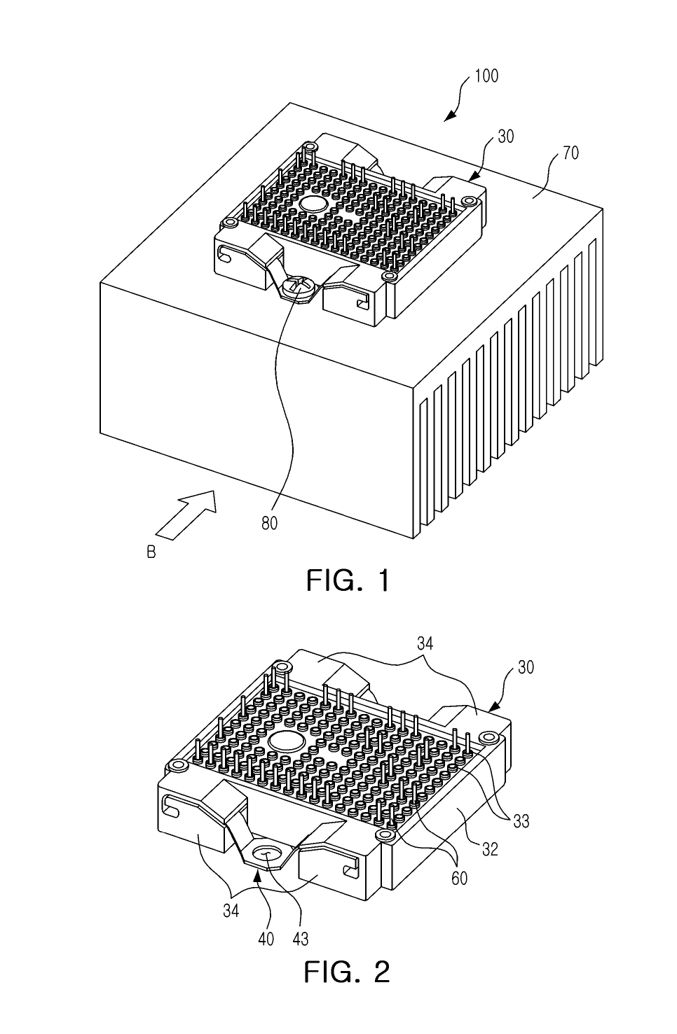

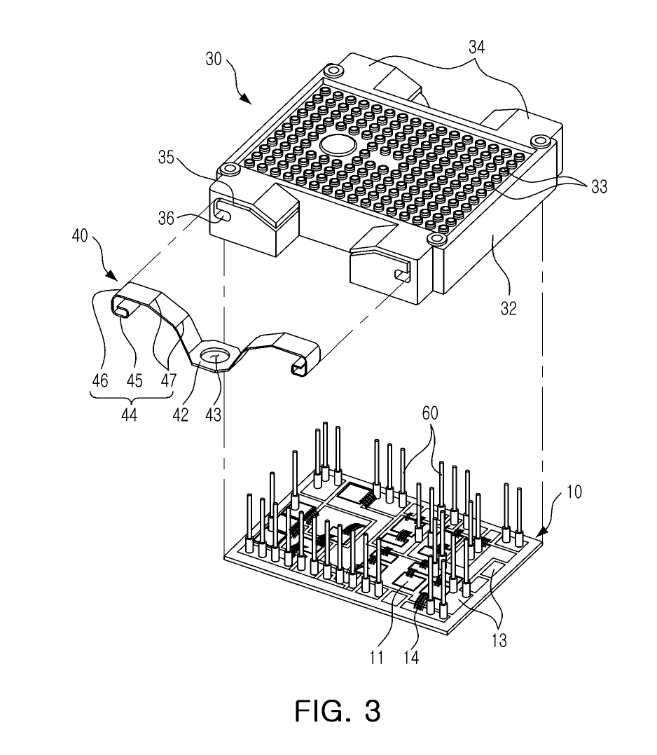

FIG. 1 is a perspective view schematically illustrating a power module according to an embodiment of the present invention, FIG. 2 is a perspective view illustrating only a housing and a substrate of the power module illustrated in FIG. 1, and FIG. 3 is an exploded perspective view of FIG. 2.

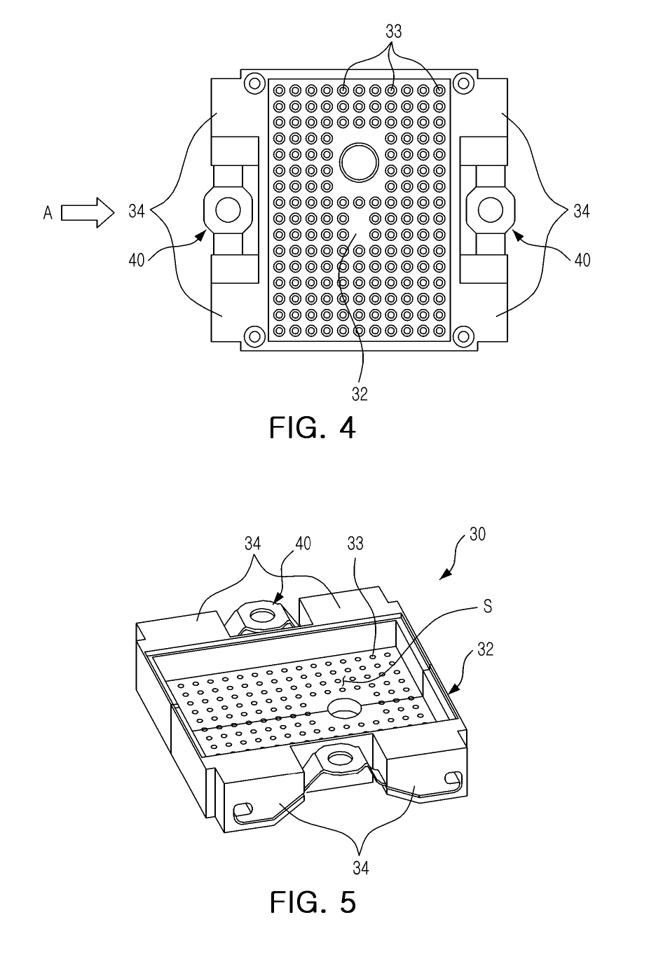

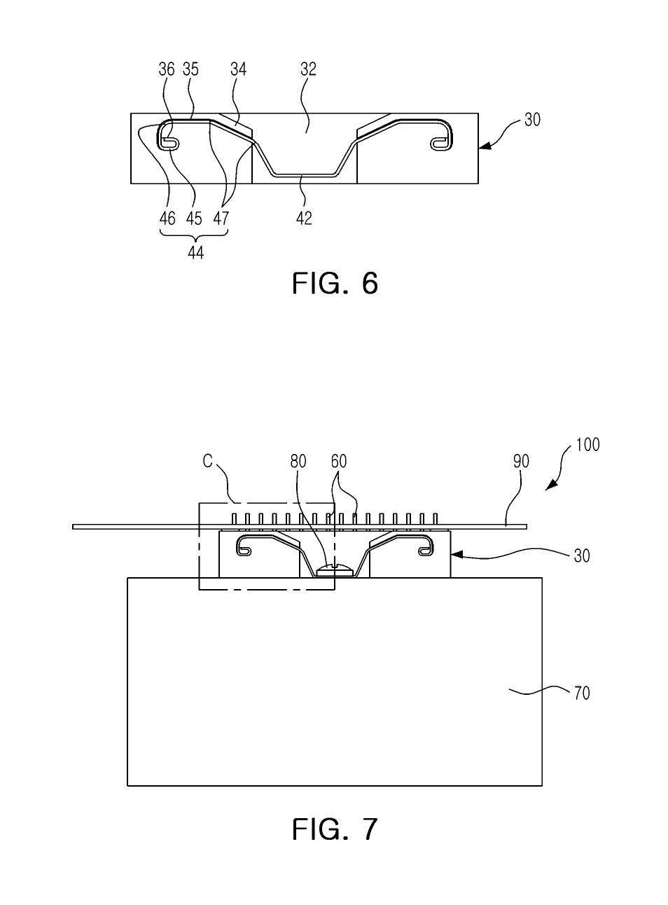

Further, FIG. 4 is a plan view schematically illustrating the housing of FIG. 2, FIG. 5 is a bottom perspective view schematically illustrating the housing of FIG. 2, and FIG. 6 is a side view in direction A of FIG. 4.

Referring to FIGS. 1 to 6, a power module 100 according to the embodiment of the invention may include a module substrate 10, electronic devices 11, an external connection terminal 60, a heat radiating substrate 70, and a housing 30.

The module substrate 10 may be a printed circuit board (PCB), a ceramic substrate, a pre-molded substrate, a direct bonded copper (DBC) substrate, or an insulated metal substrate (IMS).

As illustrated in FIG. 3, the module substrate 10 may be provided with mounting electrodes (not illustrated) for the electronic devices 11 to be described below mounted thereon, a wiring pattern 13 for electrically connecting these electrodes, and the like.

The wiring pattern 13 may use a general layer forming method, for example, chemical vapor deposition (CVD) and physical vapor deposition (PVD) or may be formed by electroplating or electroless plating. Further, the wiring pattern 13 may include a conductive material, such as a metal. For example, the wiring pattern 13 may include aluminum, an aluminum alloy, copper, a copper alloy, or a combination thereof.

Further, one surface of the module substrate 10 may have at least one or more electronic devices 11 mounted thereon.

The electronic devices 11 according to the embodiment of the invention may include a power device and a control device.

The power device may be a power circuit device for converting power or for controlling power, such as a servo driver, an inverter, a power regulator, a converter, or the like.

For example, the power device may include a power MOSFET, a bipolar junction transistor (BJT), an insulated-gate bipolar transistor (IGBT), a diode, or a combination thereof. That is, in the embodiment of the invention, the power device may include all devices mentioned above or merely a portion thereof.

In particular, the power device according to the embodiment of the invention may be configured of pairs of insulated gate bipolar transistors (IGBT) and diodes. However, this is only one example, and therefore the invention is not necessarily limited thereto.

The control device may be electrically connected to the power device through the wiring pattern 13, a bonding wire 14, and the like, and therefore may control an operation of the power device.

The control device may be, for example, a microprocessor and may further include passive devices, such as a resistor, an inverter, a capacitor, and the like or active devices such as a transistor and the like, in addition to the microprocessor.

Meanwhile, a single control device or a plurality of control devices may be provided to a single power device. That is, a type and an amount of provided control devices may be appropriately selected according to a type and an amount of power devices.

When the electronic devices 11 are electrically connected to the module substrate 10 through the bonding wire 14, the electronic devices 11 may be bonded to one surface of the module substrate 10 through an adhesive member (not illustrated). Herein, the adhesive member may have conductive properties or non-conductive properties. For example, the adhesive member may be a conductive solder, a conductive paste, or tape. Further, a solder, metal epoxy, metal paste, resin based epoxy, adhesive tape having excellent heat resistance, and the like may be used as the adhesive member.

However, the invention is not limited thereto, and the electronic device 11 maybe electrically connected to the module substrate 10 by various methods, such as a flip chip bonding method, a solder ball, and the like.

The external connection terminal 60 includes a plurality of leads, in which the individual leads may be classified as external leads connected to an external substrate (90 of FIG. 7) and internal leads fastened to the module substrate 10. That is, the external leads may refer to leads exposed to the outside of the housing 30 and the internal leads may refer to leads located in the housing 30.

In the embodiment of the invention, the external connection terminal 60 may be electrically connected to the electronic devices 11 through the wiring pattern 13 or the bonding wire 14 formed on the module substrate 10, and the like.

The external connection terminal 60 may be made of copper (Cu), aluminum (Al), or the like, but the material of the external connection terminal is not limited thereto.

The housing 30 forms an outer casing of the power module 100 and protects the electronic devices 11 and the module substrate 10 from an external environment.

The housing 30 according to the embodiment of the invention may include a body part 32 having a receiving space (S of FIG. 5) receiving the module substrate 10 formed therein, a plurality of fastening parts 34 externally protruded from the body part 32, and a fastening member 40.

The body part 32 accommodates the module substrate 10 therein. Therefore, as illustrated in FIG. 5, the receiving space S corresponding to a size of the module substrate 10 in which the electronic devices 11 are mounted may be formed in the body part 32.

In the embodiment of the present invention, the body part 32 is formed to have, for example, a hexahedral shape, but is not limited thereto, and therefore the body part 32 may be formed to have various shapes, such as a cylindrical shape, a polyprismatic shape, and the like, if necessary.

Further, a plurality of through holes 33 may be formed in one surface, that is, an upper surface of the body part 32. The external connection terminals 60 mounted on the module substrate 10 are inserted into the through holes 33, and the external leads of the external connection terminal 60 may be exposed externally from the housing 30 through the through holes 33.

The amount of through holes 33 may correspond to the amount of external connection terminals 60, corresponding to the position of the external connection terminals 60, but the invention is not limited thereto, and therefore, according to the embodiment of the invention, a plurality of through holes 33 may be formed within the upper surface of the body part 32 and may be selectively used, if necessary.

The plurality of fastening parts 34 may protrude from the sides of the body part 32. In the embodiment of the invention, the fastening parts 34 protrude outwardly from both sides of the body part 32 having a hexahedral shape. That is, the fastening parts 34 may be formed on both sides of the body part 32 disposed in parallel and may protrude in a symmetrical manner.

Further, the two fastening parts 34 may be formed each of the sides of the body part 32. In this case, the two fastening parts 34 may be spaced apart from each other by a predetermined distance. Further, a coupling portion 42 of the fastening member 40 to be described below may be disposed between the two fastening parts 34.

The individual fastening parts 34 are provided with fitting grooves 35 and fixing grooves 36. The fitting grooves 35 and the fixing grooves 36 are used as space in which portions of the fastening member 40 are fitted, and therefore may be formed to have a shape corresponding to a shape of the fastening member 40.

The fitting groove 35 may have an elastic portion 44 of the fastening member 40 inserted thereinto. Therefore, the fitting groove 35 may be formed to have a size corresponding to a thickness of the elastic portion 44 and may be formed to have a shape of an elongated groove including a bend or a curve corresponding to the shape of the elastic portion 44.

The fixing groove 36 may be formed at the end of the fitting groove 35 to be connected to the fitting groove 35. The fixing groove 36 may receive a fixing portion 45 of the fastening member 40 inserted thereinto. Therefore, the fixing groove 36 may be formed to have a wider space than that of the fitting groove 35.

The fastening member 40 is inserted into the fastening part 34 to complete the housing 30 according to the embodiment of the invention. The fastening member 40 may generally be formed by bending a flat metal plate, in detail, may be formed to have a metal leaf spring form as illustrated in FIG. 3.

Further, the fastening member 40 may include the coupling portion 42 coupled to a fixing screw (80 of FIG. 1) and the elastic portion 44 providing elastic force.

The coupling portion 42 is disposed between two elastic portions 44 and is provided with a fastening hole 43 formed therein, into which the fixing screw 80 is inserted. The coupling portion 42 may be coupled to the fastening part 34 so as to be approximately parallel to an upper surface of the heat radiating substrate (70 of FIG. 1). Therefore, when the coupling portion 42 is fastened to the heat radiating substrate 70, a lower surface of the coupling portion 42 may surface-contact the upper surface of the heat radiating substrate 70.

When the fastening member 40 is coupled to the fastening part 34, as illustrated in FIG. 6, the lower surface of the coupling portion 42 may be disposed to be higher than the lower surface of the body part 32 or the lower surface of the fastening part 34. Further, when the housing 30 is fastened to the heat radiating substrate 70, the coupling portion 42 of the fastening member 40 moves downwardly in an elastic manner by the coupling force of the fixing screw 80 and the heat radiating substrate 70. During this process, the elastic portions 44 may be elastically deformed within the fastening parts 34 and provide the elastic force to the coupling portion 42.

The elastic portions 44 may be formed at both edges of the coupling portion 42 to be disposed symmetrically with respect to each other. The elastic portions 44 may be formed in a manner extending from both edges of the coupling portion 42 and are inserted into the fitting grooves 35 of the fastening parts 34 protruded from the housing 30. Therefore, the overall shape of the elastic portions 44 may be formed similarly to the shape of the fitting grooves 35.

An end of the elastic portion 44 may be formed as the fixing portion 45 by rolling a predetermined portion thereof in a cylindrical form to thereby have expanded dimensions. The fixing portions 45 are provided to limit the movement of the fastening member 40 when the fixing screw 80 is fastened to the coupling portion 42.

That is, as the fixing portions 45 are inserted into the fixing grooves 36 of the fastening parts 34, both ends of the fastening member 40 are fixed to the fixing grooves 36 and the coupling portion 42 is fixed to the heat radiating substrate 70, and the elastic force is generated by elastic deformation in an interval between the fixing portions 45 and the coupling portion 42.

To this end, as illustrated in FIG. 3, the elastic portions 44 may include at least one curved portion 46 or at least one bent portion 47. In the embodiment of the invention, one elastic portion 44 may include one curved portion 46 and two curved portions 47. This is intended to provide elasticity to the fastening parts 34 when the coupling portion 42 is fastened to the heat radiating substrate 70.

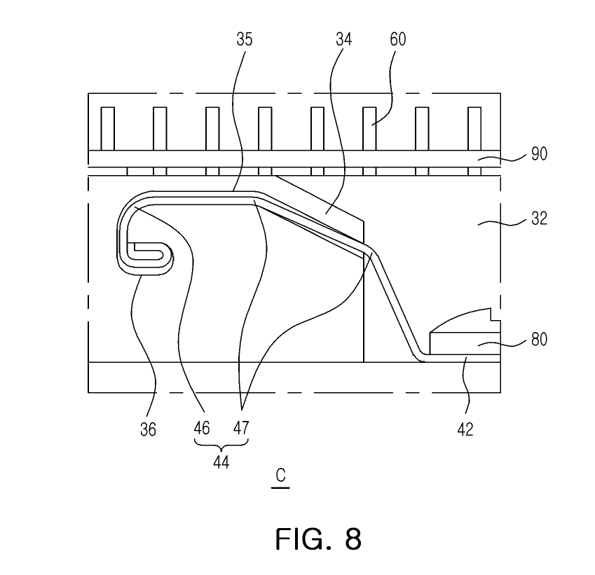

In detail, when the coupling portion 42 is fastened to the heat radiating substrate 70, the curved portions 46 or the bent portions 47 of the elastic portions 44 may be deformed in a manner such that a curved surface or a bent surface is unbent (see FIG. 8). Therefore, the elastic portions 44 may generate force maintaining the curved portions 46 or the bent portions 47 in an original form thereof, that is, elastic force, and the elastic force may be provided to the fastening parts 34.

The elastic force is continuously generated in the state in which the fastening member 40 is fastened to the heat radiating substrate 70. Therefore, the housing 30 according to the embodiment of the invention may continuously maintain adhesive force with the heat radiating substrate 70 through the elastic force.

The fastening members 40 are disposed on both sides of the body part 32 according to the embodiment of the invention. Therefore, two fixing screws 80 coupled to the two fastening members 40 are used. That is, even though the housing 30 according to the embodiment of the invention uses the two fixing screws 80, force may be applied to a total of four fastening parts 34 through the fastening member 40 to obtain a pressing effect at four points (that is, four fastening parts). Therefore, the housing 30 may be more firmly coupled to the heat radiating substrate 70.

The heat radiating substrate 70 is fastened to the lower portion of the housing 30 to discharge heat generated from the electronic devices 11 to the outside. In detail, the module substrate 10 having the electronic devices 11 fastened thereto is seated on the upper surface of the heat radiating substrate 70, and the housing 30 is fastened to the upper surface of the heat radiating substrate 70 while receiving the module substrate 10 therein.

The heat radiating substrate 70 may be a heat sink formed of a metal that may effectively radiate heat to the outside. As the material of the heat radiating substrate 70, aluminum (Al) or an aluminum alloy that may be easily used relatively inexpensively and have excellent heat conductivity may be used. However, the material of the heat radiating substrate 70 is not limited thereto, and any material having excellent heat conductivity, such as graphite, or the like, may be used.

Further, the heat radiating substrate 70 may have a plurality of projections or slits formed on an external surface thereof to extend an external area.

Meanwhile, although not illustrated, in the power module 100 according to the embodiment of the invention, the housing 30 may have a molding part formed therein. The molding part may seal the module substrate 10 and the electronic devices 11 by which the internal space of the housing 30 is filled with the molding part.

That is, the molding part may be formed to cover and seal the electronic devices 11 and the internal leads of the external connection terminal 60 bonded to the module substrate 10 to thereby protect the electronic devices 11 from the external environment.

Further, the electronic devices 11 are safely protected from external impacts by the molded part enclosing and fixing the electronic devices 11.

The molded part may be formed of an insulating material, such as resin, or the like. In particular, materials, such as a silicon gel having a high degree of heat conductivity, heat conductive epoxy, polyimide, and the like, may be used.

Next, a method of manufacturing a power module according to an embodiment of the invention will be described.

FIG. 7 is a side view in direction B of FIG. 1 and FIG. 8 is a partially enlarged view of portion C of FIG. 7. FIGS. 7 and 8 illustrate a state in which a power module is mounted on an external substrate.

Describing the method of manufacturing the power module 100 according to the embodiment of the invention with reference to FIGS. 7 and 8, the housing 30 coupled to the fastening member 40, the module substrate 10 having the electronic devices 11 mounted thereon, and the heat radiating substrate 70 are first prepared.

Here, the fastening member 40 of the housing 30 keeps an original shape as illustrated in FIG. 6, and the lower surface of the coupling portion 42 of the fastening member 40 is disposed to be higher than the lower surface of the body part 32.

Next, as illustrated in FIG. 7, the housing 30 is fastened to the heat radiating substrate 70 so that the module substrate 10 is received in the housing 30.

In this case, the fixing screw 80 presses the coupling portion 42 of the fastening member 40 downwardly and is fastened to the heat radiating substrate 70. Therefore, the fastening member 40 is elastically deformed. That is, the coupling portion 42 moves downwardly to surface-contact the heat radiating substrate 70 and the curved portions 46, the bent portions 47, and the like, of the elastic portions 44 are deformed as illustrated in FIG. 8 due to the movement of the coupling portion 42, such that the fastening member 40 may provide elastic force to the fastening parts 34.

That is, the housing 30 according to the embodiment of the invention may be firmly coupled to the heat radiating substrate 70 through the elastic force provided by the elastic deformation of the fastening member 40.

The power module 100 according to the embodiment of the invention configured as described above uses two fixing screws, but may obtain the pressing effect at four points through the fastening members 40 and the fastening parts 34. Therefore, the housing 30 may be more firmly coupled to the heat radiating substrate 70.

Further, since the elastic force provided from the two fastening members 40 is evenly applied to the four fastening parts 34, stress may be evenly distributed to the body part 32 through the fastening parts 34, without being concentrated on any one or two portions of the housing 30 according to the embodiment of the invention.

As a result, the damage to the housing 30 due to the concentration of the stress on a portion of the housing 30 may be prevented.

The power module is not limited to the above-described exemplary embodiments but may be variously modified. For example, the housing of the power module in the above-described embodiments has a rectangular parallelepiped shape, but the invention is not limited thereto. That is, the housing of the power module may have various shapes, such as a cylindrical shape, a polyprism shape, and the like, if necessary.

Further, the power module is taken as an example in the above-described embodiments, but the invention is not limited thereto. Therefore, the present inventive concept may be applied to any electronic component having at least one or more power devices packaged therein.

While the present invention has been shown and described in connection with the embodiments, it will be apparent to those skilled in the art that modifications and variations can be made without departing from the spirit and scope of the invention as defined by the appended claims.

What is claimed is:

1. A housing for a power module, comprising:
a body part having a space formed therein, the space receiving a module substrate having electronic devices mounted thereon;
a plurality of fastening parts protruded from sides of the body part; and
a fastening member having a leaf spring form and having both ends coupled to two of the fastening parts, respectively;
wherein the fastening member includes:
a coupling portion coupled to a fixing member; and
elastic portions extending from both edges of the coupling portion to be coupled to the fastening parts and elastically deformed when the coupling portion is fastened to a heat radiating substrate to provide elastic force to the fastening parts.

2. The housing for a power module of claim 1, wherein the elastic portions of the fastening member include at least one curved portion or at least one bent portion.

3. The housing for a power module of claim 1, wherein both ends of the fastening member are provided with fixing portions having expanded dimensions, and
the fixing portions limit deformation of the fastening member.

4. The housing for a power module of claim 1, wherein the coupling portion of the fastening member is disposed to be higher than a lower surface of the body part.

5. The housing for a power module of claim 1, wherein the fastening parts are provided with fitting grooves into which the elastic portions are inserted.

6. The housing for a power module of claim 1, wherein the body part has a rectangular parallelepiped shape, and
the fastening parts are formed on at least two of the sides of the body part, one side of the at least two of the sides of the body part being provided with two fastening parts disposed in a symmetrical manner.

7. The housing for a power module of claim 1, wherein the body part includes at least one or more through holes through which external connection terminals mounted on the module substrate are exposed to the outside.

8. A housing for a power module, comprising:
a plurality of fastening parts protruded from sides of a body part; and
a fastening member having both ends coupled to two of the fastening parts, respectively, and a central portion fastened to a heat radiating substrate by a fixing member.

9. A power module, comprising:
a heat radiating substrate;
a module substrate disposed on the heat radiating substrate and having at least one electronic device mounted thereon; and
a housing receiving the module substrate and fastened to the heat radiating substrate,
wherein the housing includes:
a plurality of fastening parts protruded from sides thereof; and
a fastening member having a leaf spring form and having both ends coupled to two of the fastening parts, respectively.

10. The power module of claim 9, wherein the fastening member includes:
a coupling portion surface-contacting the heat radiating substrate through a fixing screw to be fixedly coupled thereto; and
elastic portions extending from both edges of the coupling portion, respectively, to be coupled to the fastening parts and elastically deformed when the coupling portion is fastened to the heat radiating substrate to provide elastic force to the fastening parts.

11. The power module of claim 9, wherein the fastening parts are provided with fitting grooves into which the elastic portions are inserted, and
the elastic portions are elastically deformed within the fitting grooves.
